(19) United States
(12) Patent Application Publication
(10) Pub. No.: US 2026/0177900 A1
(43) Pub. Date: Jun. 25, 2026

(54) MASK BLANK LAMINATE FOR EUV LITHOGRAPHY, METHOD OF PRODUCING SAME, AND MASK FOR EUV LITHOGRAPHY

(71) Applicant: ZEON CORPORATION, Chiyoda-ku, Tokyo (JP)

(72) Inventors: Takashi TSUTSUMI, Chiyoda-ku, Tokyo (JP); Tadateru YATSUO, Chiyoda-ku, Tokyo (JP)

(73) Assignee: ZEON CORPORATION, Chiyoda-ku, Tokyo (JP)

(21) Appl. No.: 19/129,019

(22) PCT Filed: Nov. 14, 2023
(86) PCT No.: PCT/JP2023/040984

§ 371 Date: May 12, 2025

(30) Foreign Application Priority Data
Nov. 29, 2022 (JP) 2022-190330

(51) Int. Cl. G03F 1/22; G03F 7/00

(52) U.S. Cl. CPC G03F 1/22; G03F 7/0005

(57) ABSTRACT

A mask blank laminate for EUV lithography includes a mask blank substrate for EUV lithography, an organic underlayer film disposed on one surface of the substrate, and a resist film disposed on the organic underlayer film.

### TECHNICAL FIELD

The present disclosure relates to a mask blank laminate for EUV lithography and a method of producing the same, and also relates to a mask for EUV lithography.

### BACKGROUND

Photomasks that are used in microprocessing techniques of semiconductor devices can be produced by forming a resist film on a mask blank that includes a light-shielding film formed on a substrate to obtain a mask blank laminate and then performing patterning. In recent years, various improvements to mask blank laminates have been attempted (for example, refer to Patent Literature (PTL) 1 and 2).

### CITATION LIST

### Patent Literature

PTL 1: JP2007-241259A
PTL 2: WO2019/123842A1

### SUMMARY

### Technical Problem

Trends toward smaller size and higher performance of semiconductor devices in recent years have been accompanied by demand for miniaturization of lithography techniques. This has also been accompanied by a shift toward the use of exposure light of shorter wavelengths, and EUV lithography in which EUV of around 13.5 nm is used as a light source is now being adopted in practical applications. In order for the precision of EUV lithography to be adequately displayed, it is necessary for a mask for EUV lithography to have high resolution.

Accordingly, an object of the present disclosure is to provide a mask for EUV lithography having high resolution.

### Solution to Problem

Specifically, with the aim of advantageously solving the problem set forth above, (1) a presently disclosed mask blank laminate for EUV lithography comprises a mask blank substrate for EUV lithography; an organic underlayer film disposed on one surface of the substrate; and a resist film disposed on the organic underlayer film. Through the presently disclosed mask blank laminate for EUV lithography that satisfies the structure set forth above, it is possible to form a mask for EUV lithography having high resolution.

(2) In the mask blank laminate for EUV lithography according to the foregoing (1), the organic underlayer film may contain a base resin and at least one of (i) to (iii), listed below:
(i) an acid or an acid generator;
(ii) a compound including a functional group that has a function of cross-linking the base resin;
(iii) a compound including a functional group that changes polarity or acidity/basicity of the base resin.

(3) In the presently disclosed mask blank laminate for EUV lithography according to the foregoing (1) or (2), it is preferable that with regards to the organic underlayer film, in a situation in which a film is formed with a thickness of 10 nm on the substrate, is heat-treated at 130° C. for 10 minutes to obtain a thermally dried film, and a surface of the thermally dried film is brought into contact with an organic solvent that is propylene glycol monomethyl ether acetate, propylene glycol monomethyl ether, ethyl lactate, isoamyl acetate, or anisole or with a 2.38 wt % tetramethylammonium hydroxide aqueous solution for 60 seconds and then dried to obtain a post-testing dried film, thickness of the thermally dried film and thickness of the post-testing dried film satisfy a relationship in equation (1), shown below:

(thickness of post-testing dried film)/(thickness of thermally dried film)>0.95 (1).

Through the inclusion of an organic underlayer film that satisfies the condition set forth above, it is possible to even further increase the resolution of an obtained mask.

(4) In the mask blank laminate for EUV lithography according to any one of the foregoing (1) to (3), the resist film is preferably a main chain scission-type resist film that expresses lithographic performance through cleavage of a macromolecule main chain upon irradiation with radiation. When the resist film is a main chain scission-type resist film, stability over time of an obtained mask for EUV lithography can be increased.

(5) A presently disclosed method of producing a mask blank laminate for EUV lithography comprises: forming an organic underlayer film on one surface of a mask substrate for EUV lithography; heating the organic underlayer film at 150° C. or lower; and forming a resist film on the organic underlayer film. Through the presently disclosed method of producing a mask blank laminate for EUV lithography set forth above, it is possible to efficiently produce the presently disclosed mask blank laminate for EUV lithography.

(6) A presently disclosed method of producing a mask for EUV lithography comprises exposing the mask blank laminate for EUV lithography according to any one of the foregoing (1) to (4); and developing the mask blank laminate for EUV lithography that has been exposed using a developer. Through the presently disclosed method of producing a mask for EUV lithography set forth above, it is possible to form a mask for EUV lithography having high resolution.

### Advantageous Effect

According to the present disclosure, it is possible to provide a mask for EUV lithography having high resolution.

### DETAILED DESCRIPTION

The following provides a detailed description of embodiments of the present disclosure.

A mask for EUV lithography that has been produced in accordance with the present disclosure can suitably be used, for example, in the formation of a resist pattern in a production process of a semiconductor or the like, but is not specifically limited to being used in this manner.

### (Mask Blank Laminate for EUV Lithography)

A feature of the presently disclosed mask blank laminate for EUV lithography is that it includes a mask blank substrate for EUV lithography, an organic underlayer film disposed on one surface of the substrate, and a resist film disposed on the organic underlayer film. Through the presently disclosed mask blank laminate for EUV lithography that satisfies the structure set forth above, it is possible to form a mask for EUV lithography having high resolution.

### <Mask Blank Substrate for EUV Lithography>

The mask blank substrate for EUV lithography is not specifically limited and may be a substrate in which a reflective layer and an absorbing layer are provided on a glass substrate. The glass substrate is not specifically limited and may be low thermal expansion glass such as SiO₂—TiO₂ glass, for example. The reflective layer is not specifically limited and may be a layer formed of a Mo/Si multilayer reflective film, a Mo compound/Si compound multilayer reflective film, or a Si/Mo/Ru multilayer reflective film. The absorbing layer is not specifically limited and may be a layer containing a material that has a high absorption coefficient with respect to EUV light such as Cr, Ta, or a nitride thereof (TaN, etc.), for example.

### <Organic Underlayer Film>

The organic underlayer film is not specifically limited and may be an organic underlayer film that is commonly known in the relevant field. In particular, it is preferable that the organic underlayer film contains a base resin and at least one of (i) to (iii), listed below.
(i) An acid or an acid generator
(ii) A compound including a functional group that has a function of cross-linking the base resin
(iii) A compound including a functional group that changes polarity or acidity/basicity of the base resin.

The base resin may be an acrylic acid ester copolymer, a methacrylic acid ester copolymer, an epoxy resin or derivative thereof, a phenol resin or derivative thereof, a naphthol resin or derivative thereof, a vinyl ether copolymer, a maleic acid copolymer or derivative thereof, a polyacrylamide copolymer, a polymethacrylamide copolymer, a substituted styrene copolymer, a maleimide copolymer, a polyethersulfone, a polyester, or a polyamide. More specific examples of the base resin include a polymer having a repeating unit structure including a halogen atom that is disclosed in WO2008/105266A1, a polymer including a unit structure having a lactone ring and a unit structure having a hydroxy group that is disclosed in WO2015/093323A1, a polymer having diphenyl sulfone or a derivative thereof introduced into a main chain through an ether bond that is disclosed in WO2012/067040A1, a condensation polymer that is disclosed in WO2013/018802A1, a polymer having a sulfonyl group introduced at a terminal that is disclosed in WO2015/163195A1, a polymer having a structural unit including a urea bond that is disclosed in WO2018/143359A1, and a carboxylic acid-grafted polymer that is disclosed in WO2019/241402A1.

The acid or acid generator may be a compound that is described in any of the aforementioned publications. More specifically, the acid may be a sulfonic acid compound or carboxylic acid compound such as p-toluenesulfonic acid, trifluoromethanesulfonic acid, pyridinium-p-toluenesulfonate, pyridinium-p-hydroxybenzenesulfonate, salicylic acid, camphorsulfonic acid, 5-sulfosalicylic acid, 4-chlorobenzenesulfonic acid, 4-phenolsulfonic acid, methyl 4-phenolsulfonate, benzenedisulfonic acid, 1-naphthalenesulfonic acid, citric acid, benzoic acid, or hydroxybenzoic acid. The acid generator may be an onium salt-based acid generator such as bis(4-tert-butylphenyl)iodonium trifluoromethanesulfonate or triphenylsulfonium trifluoromethanesulfonate, a halogen-containing compound-based acid generator such as phenyl-bis(trichloromethyl)-s-triazine, or a sulfonic acid-based acid generator such as benzoin tosylate or N-hydroxysuccinimide trifluoromethanesulfonate, which are acid generators that generate an acid upon irradiation with an electron beam or EUV; or may be 4-acetoxyphenyldimethylsulfonium hexafluoroarsenate, benzyl-4-hydroxyphenylmethyl sulfonium hexafluoroantimonate, 4-hexafluoroantimonate, dibenzyl-4-acetoxyphenylbenzylmethylsulfonium hydroxyphenylsulfonium hexafluoroantimonate, 4-acetoxyphenylbenzylsulfonium hexafluoroantimonate, 3-benzylbenzothiazolium hexafluoroantimonate, 2,4,4,6-tetrabromocyclohexadienone, benzoin tosylate, or 2-nitrobenzyl tosylate, which are thermal acid generators.

The compound including a functional group that has a function of cross-linking the base resin may be a melamine-based compound that includes a cross-link forming substituent such as a methylol group or a methoxymethyl group, a substituted urea-based compound, or a macromolecular compound that includes an epoxy group or a vinyl ether group. Moreover, the compound including a functional group that changes polarity of the base resin may be an additive having a specific structure (structural unit represented by the following formula (1)) that is disclosed in WO2015/012172A1. Furthermore, the compound including a functional group that changes acidity/basicity of the base resin may be a polymer including a specific repeating structural unit having an amino group protected by a tert-butoxycarbonyl group in a main chain that is disclosed in WO2013/133088A1 or a polymer having a specific terminal structure (structure represented by the following formula (2)) that is disclosed in WO2013/141015A1.

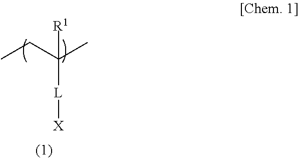

In formula (1), R¹ represents a hydrogen atom or a methyl group, L represents a single bond or a divalent linking group, and X represents an aliphatic hydrocarbon group, an alicyclic hydrocarbon group, or a heterocyclic group having an oxygen atom as a heteroatom and does not include a hydroxy group.

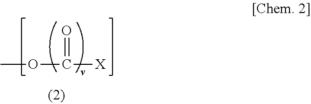

In formula (2), X represents a phenyl group, a naphthyl group, or an anthracenyl group that is substituted with one or more selected from the group consisting of a halogen atom, a hydroxy group, and a linear or branched alkoxy group having a carbon number of 1 to 6, and v represents 0 or 1.

With regards to the organic underlayer film, it is preferable that in a situation in which a film is formed with a thickness of 10 nm on the substrate, is heat-treated at 130° C. for 10 minutes to obtain a thermally dried film, and a surface of the thermally dried film is brought into contact with an organic solvent that is propylene glycol monomethyl ether acetate, propylene glycol monomethyl ether, ethyl lactate, isoamyl acetate, or anisole or with a 2.38 wt % tetramethylammonium hydroxide aqueous solution (hereinafter, also referred to as a TMAH solution) for 60 seconds and then dried to obtain a post-testing dried film, the thickness of the thermally dried film and the thickness of the post-testing dried film satisfy a relationship in equation (1), shown below.

$$( Thickness of post - testing dried film ) / \\ ( Thickness of thermally dried film ) > 0.95 \qquad ( 1 )$$

In the test described above, the temperature when the surface of the thermally dried film is brought into contact with the organic solvent or the TMAH solution for 60 seconds is 25° C. Moreover, in this contacting, the surface is brought into contact with any one of the organic solvents listed above or the TMAH solution for 60 seconds. No specific limitations are placed on the specific mode of “contact”, and this can be performed in accordance with any development treatment format that can be adopted in typical mask substrate development treatment. Specifically, a spraying technique, a puddle technique, or a dipping technique may be adopted as the development treatment format. In particular, a puddle technique is adopted in the present testing method. Furthermore, after the surface of the thermally dried film has been brought into contact with the organic solvent or TMAH solution, the organic solvent or TMAH solution is removed from the surface of the thermally dried film. The method of removal is air drying (spin drying).

In a case in which the resist film is a chemically amplified resist film, any one of propylene glycol monomethyl ether acetate, propylene glycol monomethyl ether, and ethyl lactate is adopted as the organic solvent that is used in the test. For example, the test procedure may involve first implementing the test using propylene glycol monomethyl ether acetate, and, in a situation in which it is determined that the relationship in equation (1) is not satisfied, sequentially implementing the test in order with propylene glycol monomethyl ether and ethyl lactate to investigate whether the relationship in equation (1) is satisfied. In a case in which the resist film is a main chain scission-type resist film, isoamyl acetate is adopted when the constituent polymer of the resist film is a fluorine-containing polymer, whereas anisole is adopted when the constituent polymer of the resist film is a non-fluorine-containing polymer.

When the value of (thickness of post-testing dry film)/(thickness of thermally dried film) is 0.95 or more, film thinning can be inhibited, and the resolution of a mask pattern obtained through exposure and development steps is even better.

### <Resist Film>

The resist film may be a main chain scission-type resist film or a chemically amplified resist film. In particular, it is preferable that the resist film is a main chain scission-type resist film that expresses lithographic performance through cleavage of a macromolecule main chain upon irradiation with radiation. When the resist film is a main chain scission-type resist film, it is possible to increase stability over time of an obtained mask for EUV lithography.

In a mask process for producing a mask for lithography, resting time until exposure after application of a coating material of a resist composition and resting time from exposure until development tend to be long compared to in a wafer process using a silicon wafer. Therefore, it is preferable that a mask for lithography has high stability over time. The characteristics of a chemically amplified resist film mean that the chemical nature of the chemically amplified resist film tends to change more readily than that of a main chain scission-type resist when there is a long resting time such as described above. Note that this tendency is thought to be more noticeable in a situation in which the resist film has been stacked on an organic underlayer film. Moreover, in a situation in which the resist film is stacked on an organic underlayer film and in which the organic underlayer film is formed of a thermosetting resin, a large amount of an unreacted constituent substance of the organic underlayer film may remain as a low-molecular weight component in a case in which the baking temperature of the organic underlayer film has been inadequate. This low-molecular weight component can instigate a chemical reaction in the resist film due to interlayer migration of the low-molecular weight component during application and pre-bake treatment of a resist composition on the organic underlayer film. As a result, the loss of stability of performance over time of a chemically amplified resist film is a concern. When the resist film is a main chain scission-type resist film, there is a low risk of a chemical reaction occurring between the constituent polymer of the resist film and a low-molecular weight component originating from the organic underlayer film regardless of the structure of the resist film. Accordingly, when the resist film is a main chain scission-type resist film, there is a low risk of an undesirable chemical reaction being instigated due to a produced low-molecular weight component even in a situation in which the organic underlayer film has been baked at a low temperature, for example, and thus it is advantageous for the resist film to be a main chain scission-type resist film in terms of easily constructing a mask process in which the organic underlayer film is adopted.

The polymer that is used for forming the main chain scission-type resist film is not specifically limited and may be a polymer that is commonly known in the relevant field, for example. This polymer can be a fluorine-containing polymer or can be a non-fluorine-containing polymer. Examples of prior art disclosing such polymers include JP2019-211531A, WO2019/150966A1, WO2021/261297A1, and WO2022/190714A1. Moreover, a known solvent can be adopted as a solvent that is used to form the main chain scission-type resist film without any specific limitations so long as it is a solvent that can dissolve the above-described polymer. In particular, it is preferable to use anisole, propylene glycol monomethyl ether acetate (PGMEA), cyclopentanone, cyclohexanone, hexyl acetate, or isoamyl acetate as the solvent from a viewpoint of improving coatability of a main chain scission-type resist composition. Note that one solvent may be used individually, or a plurality of solvents may be used as a mixture.

A polymer and a solvent that are commonly known in the relevant field (for example, refer to WO2022/172597A1, WO2020/095641A1, WO2020/045535A1, JP2022-145559A, JP2022-123567A, JP2018-109764A, and JP2018-25778A) can be compounded without any specific limitations as a polymer and a solvent that are used to form a chemically amplified resist film.

The resist film may further contain any additives as necessary in addition to the above-described polymer. Such additives can be added in an amount that is appropriate according to the application without any specific limitations.

### (Method of Producing Mask Blank Laminate for EUV Lithography)

A feature of the presently disclosed method of producing a mask blank laminate for EUV lithography is that it includes: forming an organic underlayer film on one surface of a mask substrate for EUV lithography (organic underlayer film formation step); heating the organic underlayer film at 150° C. or lower (organic underlayer film heating step); and forming a resist film on the organic underlayer film (resist film formation step). Through the presently disclosed method of producing a mask blank laminate for EUV lithography set forth above, it is possible to efficiently produce the presently disclosed mask blank laminate for EUV lithography.

### <Organic Underlayer Film Formation Step>

In the organic underlayer film formation step, a composition for an organic underlayer film is applied onto one surface of a mask substrate for EUV lithography to form an organic underlayer film. The composition for an organic underlayer film may be a composition for an organic underlayer that is commonly known in the relevant field. In particular, it is preferable that the composition for an organic underlayer film contains a base resin, a compound having a functional group that generates an acid upon heating or irradiation with radiation, and a compound including a functional group having a function of cross-linking and increasing the molecular weight of the base resin through the action of an acid. The base resin and other compounds can suitably be any of those that were previously described. Note that the mask substrate for EUV lithography can suitably be any of those that were previously described.

### <Organic Underlayer Film Heating Step>

In the organic underlayer film heating step, the organic underlayer film that has been formed in the above-described organic underlayer film formation step is heated at 150° C. or lower. The heating temperature is preferably 130° C. or lower, and more preferably 125° C. or lower. Moreover, the heating temperature is preferably 90° C. or higher. When the heating temperature is not higher than any of the upper limits set forth above, it is possible to efficiently inhibit degradation caused by heat with respect to a reflective layer formed of a Mo/Si multilayer reflective film or the like that is included in the mask blank substrate for EUV lithography. Moreover, when the heating temperature is not lower than the lower limit set forth above, stability of the organic underlayer film can be increased.

### <Resist Film Formation Step>

In the resist film formation step, a resist film is formed on the organic underlayer film that has undergone the organic underlayer film heating step. In formation of a resist film, a specific resist composition is applied onto the organic underlayer film to obtain a coating layer, and then a solvent is removed from the obtained coating layer to form a resist film. The method by which the solvent is removed from the coating layer is not specifically limited and can be a drying method that is typically used in formation of a resist film.

### (Method of Producing Mask for EUV Lithography)

A feature of the presently disclosed method of producing a mask for EUV lithography is that it includes: exposing the mask blank laminate for EUV lithography set forth above (exposure step); and developing the mask blank laminate for EUV lithography that has been exposed using a developer (development step). Through the presently disclosed method of producing a mask for EUV lithography set forth above, it is possible to form a mask for EUV lithography having high resolution.

### <Exposure Step>

In the exposure step, the presently disclosed mask blank laminate for EUV lithography is exposed. During exposure, the resist film constituting an outermost surface of the mask blank laminate for EUV lithography is irradiated with exposure light at a specific location so as to write a desired pattern. Through irradiation with exposure light, a latent pattern is formed in the resist film.

A post-exposure bake step of heating the resist film after the exposure step can optionally be implemented. The heating temperature and the heating time are not specifically limited and may be in accordance with an established method in the relevant field.

### <Development Step>

In the development step, the latent pattern of the resist film that has undergone the exposure step (and the optional post-exposure bake step) is developed to form a developed film on the workpiece.

Development of the resist film can be performed by bringing the resist film into contact with a developer, for example. The method by which the resist film and the developer are brought into contact is not specifically limited and can be a method using a known technique such as immersion of the resist film in the developer or application of the developer onto the resist film. Note that the developer can be selected as appropriate according to the properties of a polymer that has been used to form the resist film, for example. Known developers can be used as the developer without any specific limitations. Moreover, one developer may be used individually, or two or more developers may be used as a mixture in a freely selected ratio.

A step of removing the developer after the development step can optionally be implemented. Removal of the developer can be performed using a rinsing liquid, for example. The rinsing liquid is not specifically limited so long as it does not dissolve the resist pattern and can be water or a solution containing a typical organic solvent. In selection of the rinsing liquid, it is preferable to select a rinsing liquid that readily mixes with the developer.

### INDUSTRIAL APPLICABILITY

According to the present disclosure, it is possible to provide a mask for EUV lithography having high resolution.

1. A mask blank laminate for EUV lithography comprising:
a mask blank substrate for EUV lithography;
an organic underlayer film disposed on one surface of the substrate; and
a resist film disposed on the organic underlayer film.

2. The mask blank laminate for EUV lithography according to claim 1, wherein the organic underlayer film contains a base resin and at least one of (i) to (iii), listed below:
(i) an acid or an acid generator;
(ii) a compound including a functional group that has a function of cross-linking the base resin;
(iii) a compound including a functional group that changes polarity or acidity/basicity of the base resin.

3. The mask blank laminate for EUV lithography according to claim 1, wherein
with regards to the organic underlayer film, in a situation in which a film is formed with a thickness of 10 nm on the substrate, is heat-treated at 130° C. for 10 minutes to obtain a thermally dried film, and a surface of the thermally dried film is brought into contact with an organic solvent that is propylene glycol monomethyl ether acetate, propylene glycol monomethyl ether, ethyl lactate, isoamyl acetate, or anisole or with a 2.38 wt % tetramethylammonium hydroxide aqueous solution for 60 seconds and then dried to obtain a post-testing dried film, thickness of the thermally dried film and thickness of the post-testing dried film satisfy a relationship in equation (1), shown below:
$$( t hickness of post - testing dried film ) / \\ ( thickness of thermally dried film ) > 0.95 . \qquad ( 1 )$$

4. The mask blank laminate for EUV lithography according to claim 1, wherein the resist film is a main chain scission-type resist film that expresses lithographic performance through cleavage of a macromolecule main chain upon irradiation with radiation.

5. A method of producing the mask blank laminate for EUV lithography according to claim 1, comprising:
forming an organic underlayer film on one surface of a mask substrate for EUV lithography;
heating the organic underlayer film at 150° C. or lower; and
forming a resist film on the organic underlayer film.

6. A method of producing a mask for EUV lithography comprising:
exposing the mask blank laminate for EUV lithography according to claim 1; and
developing the mask blank laminate for EUV lithography that has been exposed using a developer.
